(19) United States
(12) Patent Application Publication
(10) Pub. No.: US 2023/0223734 A1
(43) Pub. Date: Jul. 13, 2023

(54) SYSTEMS AND METHODS FOR CONTROLLING A CENTER WAVELENGTH

(71) Applicant: Cymer, LLC, San Diego, CA (US)

(72) Inventors: Kuo-Tai Teng, Poway, CA (US); Yingbo Zhao, San Diego, CA (US); James Michael Simonelli, San Diego, CA (US)

(21) Appl. No.: 17/927,921

(22) PCT Filed: May 5, 2021
(86) PCT No.: PCT/US2021/030825

§ 371 Date: Nov. 28, 2022

Related U.S. Application Data
(60) Provisional application No. 63/036,700, filed on Jun. 9, 2020.
(60) Provisional application No. 63/079,191, filed on Sep. 16, 2020.

(51) Int. Cl. H01S 3/13; G03F 7/20; H01S 3/08

(52) U.S. Cl. CPC H01S 3/13; G03F 7/70025; G03F 7/70041; G03F 7/70575; H01S 3/08004; H01S 3/034

(57) ABSTRACT

The present disclosure is directed to systems and methods for controlling a center wavelength. In one example, a method includes estimating a center wavelength error. The method also includes determining a first actuation amount for a first actuator controlling movement a first prism based on the estimated center wavelength error. The method also includes actuating the first actuator based on the actuation amount. The method also includes determining whether the first prism is off-center. The method also includes, in response to determining that the first prism is off-center, determining a second actuation amount for the first actuator and determining a third actuation amount for a second actuator for controlling movement of a second prism. The method also includes actuating the first actuator and the second actuator based on the second and third actuation amounts, respectively. The method finds application in multi-focal imaging operations.

### CROSS REFERENCE TO RELATED APPLICATIONS

This application claims priority to U.S. Application No. 63/036,700 filed Jun. 9, 2020, and also claims priority to U.S. Application No. 63/079,191 filed Sep. 16, 2020, both titled SYSTEMS AND METHODS FOR CONTROLLING A CENTER WAVELENGTH, and both of which are incorporated herein in their entireties by reference.

### FIELD

The present disclosure relates to laser systems such as excimer lasers that produce light and systems and methods for controlling a center wavelength thereof

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate, a lithographic apparatus may use electromagnetic radiation. The wavelength of this radiation determines the minimum size of features which can be formed on the substrate. A lithographic apparatus may use extreme ultraviolet (EUV) radiation, having a wavelength within the range of 4-20 nm, for example 6.7 nm or 13.5 nm, or deep ultraviolet (DUV) radiation, having a wavelength in the range of about 120 to about 400 nm, for example 193 or 248 nm.

A master oscillator power amplifier (MOPA) is a two-stage optical resonator arrangement that produces a highly coherent amplified light beam. The performance of the MOPA can depend critically on the alignment of the master oscillator (MO). Alignment of the MO can include alignment of a gas discharge chamber, alignment of an input/output optical element, and alignment of a spectral feature adjuster.

However, alignment of the MO can be time consuming and require several hours of manual maintenance. Further, monitoring and adjustment of the MO alignment can inhibit or block the outputted light beam, for example, to a DUV lithographic apparatus.

Additionally, as the apparatus experiences thermal and other transients, wavelength stability is affected. In a single-color mode, two actuators, i.e., a stepper motor and a Piezoelectric transducer (PZT), work in conjunction with one another to stabilize the center wavelength. In operation, the stepper motor has limited resolution, and as such, the PZT is used as the primary actuator. However, in a two-color mode, wavelength stability is based on a central wavelength, i.e., a mean of two alternating spectra, and in this mode, the PZT is tasked with the production of the waveform that generates the alternating wavelengths.

### SUMMARY

Accordingly, there is a need to control the center wavelength.

In some embodiments, the present disclosure is directed to a system and method for controlling a center wavelength for an imaging operation. The system may include: a first actuator configured to control movement of a first prism, a second actuator configured to control movement of a second prism, and a controller configured to: estimate a center wavelength error; determine a first actuation amount for the first actuator based on the estimated center wavelength error; cause the first actuator to actuate based on the first actuation amount; determine whether the first prism is off-center; in response to determining that the first prism is off-center, determine a second actuation amount for the first actuator and determine a third actuation amount for the second actuator; and cause the first and second actuators to actuate based on the second and third actuation amounts, respectively.

The method may include estimating a center wavelength error. The method may also include determining a first actuation amount for a first actuator controlling movement of a first prism based on the estimated center wavelength error. The method may also include actuating the first actuator based on the first actuation amount. The method may also include determining whether the first prism is off-center. The method may also include, in response to determining that the first prism is off-center, determining a second actuation amount for the first actuator and determining a third actuation amount for a second actuator for controlling movement of a second prism. The method may also include actuating the first actuator and the second actuator based on the second and third actuation amounts, respectively. In some embodiments, the method may be executed using the system.

In some embodiments, the estimating the center wavelength error may include calculating a first average of a center wavelength at odd bursts and a second average of the center wavelength at even bursts and determining an average of the first and second averages, wherein the center wavelength error is based on the average of the first and second averages.

In some embodiments, the determining the first actuation amount may include determining a difference between a target center wavelength and the estimated center wavelength and determining the first actuation amount based on the difference between the target center wavelength and the estimated center wavelength.

In some embodiments, the determining the difference between the target center wavelength and the estimated center wavelength may include determining the difference using a digital filter.

In some embodiments, determining the third actuation amount for the second actuator may be based on a position of the first prism after actuating the first actuator based on the second actuation amount.

In some embodiments, the determining the third actuation amount may further include determining the third actuation amount to reduce the difference between the target center wavelength and the estimated wavelength.

In some embodiments, the imaging operation comprises a multi-focal imaging operation, and the method may further include operating a light source in a two-color mode. In some embodiments, operating the light source in the two-color mode may include: generating, using a first laser chamber module, a first beam of laser radiation at a first wavelength; generating, using a second laser chamber module, a second beam of laser radiation at a second wavelength; and combining, using a beam combiner, the first and second laser radiations along a common output beam path. In some embodiments, the estimating a center wavelength error may include estimating a center wavelength error of the first beam of laser radiation. In some embodiments, in the two-color mode, a wavelength target may alternate between two known setpoints within a burst (e.g., every pulse), and a PZT may be used in order to track the fast-changing target that leaves little margin to control the center wavelength.

In some embodiments, the present disclosure is directed to a system and method for controlling a center wavelength. The system may include: a light source configured to generate a light beam; a first actuator configured to control movement of a first prism; a second actuator configured to control movement of a second prism; and a controller. The controller may be configured to: determine a wavelength error of the light beam generated by the light source; determine whether the wavelength error is greater than a first threshold value; in response to determining that the wavelength error is greater than the first threshold value, cause the first actuator to move a first step size; in response to determining that the wavelength error is less than the first threshold value: determine an average wavelength error; determine whether the average wavelength error is greater than a second threshold value different than the first threshold value; in response to determining that the average wavelength error is greater than the second threshold value, cause the first actuator to move a second step size and enable a low pass filter; and in response to determining that the average wavelength error is less than the second threshold value, enable the low pass filter, update a voltage applied to a second actuator, and cause the first actuator to move a third step size.

The method may include determining a wavelength error of a light beam generated by a light source. The method may also include determining whether the wavelength error is greater than a first threshold value. The method may also include, in response to determining that the wavelength error is greater than the first threshold value, moving a first actuator a first step size, the first actuator being configured to control movement of a first prism. In response to determining that the wavelength error is less than the first threshold value, The method may also include: determining an average wavelength error; determining whether the average wavelength error is greater than a second threshold value different than the first threshold value; in response to determining that the average wavelength error is greater than the second threshold value, moving the first actuator a second step size and enabling a low pass filter; and in response to determining that the average wavelength error is less than the second threshold value, enabling the low pass filter, updating a voltage applied to a second actuator, and moving the first actuator a third step size, the second actuator being configured to control movement of a second prism. In some embodiments, the method may be executed using the system.

In some embodiments, the determining the wavelength error may include measuring a central wavelength of the light beam generated by the light source and determining a difference between the central wavelength and a target center wavelength.

In some embodiments, the method may further include determining whether a shot number of a pulse of the light source is a multiple of an update interval and, in response to determining that the shot number is equal to the update interval, updating the voltage applied to the second actuator.

In some embodiments, the method may further include disabling the low pass filter and movement of a second actuator in response to determining that the wavelength error is greater than the first threshold value.

In some embodiments, the first step size is a fixed step size of the actuator.

In some embodiments, the second step size is a function of the wavelength error.

In some embodiments, the third step size is a function of the voltage applied to second actuator.

In some embodiments, the moving the first actuator with the second step size includes moving the first actuator every n pulses, with n being greater than one.

In some embodiments, the average wavelength error is based on the wavelength error and an average of a plurality of wavelength errors over a number of pulses.

In some embodiments, the method comprises controlling the center wavelength in a multi-focal imaging operation, and the method may further include operating the light source in a two-color mode. In some embodiments, operating the light source in the two-color mode may include: generating, using a first laser chamber module, a first beam of laser radiation at a first wavelength; generating, using a second laser chamber module, a second beam of laser radiation at a second wavelength; and combining, using a beam combiner, the first and second laser radiations along a common output beam path. In some embodiments, the determining the wavelength error of the light beam generated by the light source comprises determining a center wavelength error of the first beam of laser radiation In some embodiments, in the two-color mode, a wavelength target may alternate between two known setpoints within a burst (e.g., every pulse), and a PZT may be used in order to track the fast-changing target that leaves little margin to control the center wavelength.

In some embodiments, the present disclosure is directed to a system and method for controlling a center wavelength for a multi-focal imaging operation. The system may include: an actuator configured to control movement of a prism; and a controller configured to: combine a dither waveform with an offset value for moving the actuator; generate a pulse-to-pulse wavelength based on the dither waveform and the offset value; generate a rolling average of the center wavelength based on the pulse-to-pulse wavelength for a plurality of pulses; estimate a drift rate to predict a center wavelength of a future pulse; and update the offset value based on the estimated drift rate.

The method may include combining a dither waveform with an offset value for moving an actuator controlling movement of a prism. The method may also include generating a pulse-to-pulse wavelength based on the dither waveform and the offset value. The method may also include generating a rolling average of the center wavelength based on the pulse-to-pulse wavelength for a plurality of pulses. The method may also include estimating a drift rate to predict a center wavelength of a future pulse. The method may also include updating the offset value based on the estimated drift rate. In some embodiments, the method may be executed using the system.

In some embodiments, the offset value is based on a direct current (DC) voltage.

In some embodiments, an initial value of the DC voltage is zero volts.

In some embodiments, the offset value comprises a first offset value, and the estimating the drift rate may include estimating the drift rate based on the rolling average of the center wavelength, the first offset value, and a second offset value moving a second actuator controlling movement of a second prism.

In some embodiments, the estimating the drift rate may include estimating an accumulated center wavelength drift rate using a Kalman filter framework.

In some embodiments, the estimating the drift rate may include predicting the center wavelength N pulses ahead of a current pulse.

In some embodiments, the estimating the drift rate may include converting the Kalman filter framework into a Kalman predictor to predict the center wavelength N pulses ahead of the current pulse.

In some embodiments, the pulse-to-pulse wavelength for a plurality of pulses comprises a wavelength of a current pulse.

In some embodiments, the updating the offset value may include updating the offset value based on the rolling average of the center wavelength at an end of a burst.

In some embodiments, the multi-focal imaging operations include a two-color mode, and the method may further include operating a light source in the two-color mode. In some embodiments, operating the light source in the two-color mode may include: generating, using a first laser chamber module, a first beam of laser radiation at a first wavelength; generating, using a second laser chamber module, a second beam of laser radiation at a second wavelength; and combining, using a beam combiner, the first and second laser radiations along a common output beam path.

Further features and exemplary aspects of the embodiments, as well as the structure and operation of various embodiments, are described in detail below with reference to the accompanying drawings. It is noted that the embodiments are not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the embodiments and, together with the description, further serve to explain the principles of the embodiments and to enable a person skilled in the relevant art(s) to make and use the embodiments.

FIG. 1 is a schematic illustration of a lithographic apparatus, according to an exemplary embodiment.

FIG. 2 is a schematic top plan illustration of a light source apparatus, according to an exemplary embodiment.

FIG. 3 is a schematic partial cross-sectional illustration of a gas discharge stage of the light source apparatus shown in FIG. 2, according to an exemplary embodiment.

FIG. 4 is a schematic partial cross-sectional illustration of a gas discharge stage of the light source apparatus shown in FIG. 2, according to an exemplary embodiment.

FIG. 5 illustrates a method for adjusting a center wavelength for multi-focal imaging, according to an embodiment.

FIGS. 6A-B, 7, and 8 illustrate methods for adjusting a center wavelength for multi-focal imaging, according to some embodiments.

FIG. 9 illustrates a flow diagram for aligning a gas discharge stage, according to an exemplary embodiment.

FIG. 10 is an example computer system useful for implementing various embodiments of this disclosure.

The features and exemplary aspects of the embodiments will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this present invention. The disclosed embodiment(s) merely exemplify the present invention. The scope of the invention is not limited to the disclosed embodiment(s). The present invention is defined by the claims appended hereto.

The embodiment(s) described, and references in the specification to “one embodiment,” “an embodiment,” “an exemplary embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Embodiments of the disclosure may be implemented in hardware, firmware, software, or any combination thereof. Embodiments of the disclosure may also be implemented as instructions stored on a tangible machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

Exemplary Lithographic System

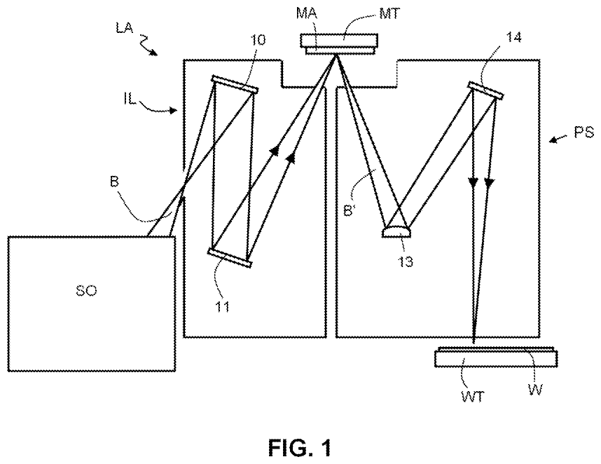

FIG. 1 shows a lithographic system comprising a radiation source SO and a lithographic apparatus LA. The radiation source SO is configured to generate an EUV and/or a DUV radiation beam B and to supply the EUV and/or DUV radiation beam B to the lithographic apparatus LA. The lithographic apparatus LA comprises an illumination system IL, a support structure MT configured to support a patterning device MA (e.g., a mask), a projection system PS, and a substrate table WT configured to support a substrate W.

The illumination system IL is configured to condition the EUV and/or DUV radiation beam B before the EUV and/or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV and/or DUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV and/or DUV radiation beam B interacts with the patterning device MA (e.g., a transmissive mask for DUV, or a reflective mask for EUV). As a result of this interaction, a patterned EUV and/or DUV radiation beam B′ is generated. The projection system PS is configured to project the patterned EUV and/or DUV radiation beam B′ onto the substrate W. For that purpose, the projection system PS may comprise a plurality of mirrors 13, 14 which are configured to project the patterned EUV and/or DUV radiation beam B′ onto the substrate W held by the substrate table WT. The projection system PS may apply a reduction factor to the patterned EUV and/or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV and/or DUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

Exemplary Light Source Apparatus

As discussed above, a master oscillator power amplifier (MOPA) is a two-stage optical resonator arrangement. The master oscillator (MO) (e.g., first optical resonator stage) produces a highly coherent light beam (e.g., from a seed laser). The power amplifier (PA) (e.g., second optical resonator stage) increases the optical power of the light beam while preserving the beam properties. The MO can include a gas discharge chamber, an input/output optical element (e.g., optical coupler (OC)), and a spectral feature adjuster (e.g., linewidth narrowing module (LNM)). The input/output optical element and the spectral feature adjuster can surround the gas discharge chamber to form an optical resonator.

Performance of the MOPA depends critically on the alignment of the MO. Alignment of the MO can include alignment of the gas discharge chamber, alignment of the OC, and alignment of the LNM. Each of the alignments (e.g., chamber, OC, LNM, etc.) can contribute to alignment errors and variations in the MO over time. However, alignment of the MO can be time consuming and require several hours of manual maintenance (e.g., synchronized performance maintenance (SPM)). Additionally, initial alignment can be difficult (e.g., trial and error) if the chamber, OC, and LNM are drastically misaligned (e.g., no initial reference point). Further, monitoring and adjustment of the MO alignment can inhibit (e.g., block) the outputted light beam (e.g., a DUV light beam), for example, to a DUV lithographic apparatus.

Imaging light (e.g., visual laser beam) can be projected on the chamber, OC, and LNM (e.g., sequentially or simultaneously) to illuminate and direct alignment of the OC and/or the LNM along an optical axis of the chamber (e.g., first and second optical ports). Amplified spontaneous emission (ASE) from the gas discharge chamber can act as a beacon (e.g., reference point) to facilitate boresighting (e.g., laser boresighting) of the imaging light along an optical axis of the MO cavity (e.g., along the optical axis of the chamber, the OC, and the LNM). Additionally, the ASE can be used to initially align the chamber with the optical axis of the MO cavity (e.g., coarse alignment). Further, a sensing apparatus (e.g., a camera) can be used to visually investigate different object planes within the MO (e.g., chamber ports, OC aperture, LNM aperture, etc.) and quantify any alignment errors (e.g., image comparison). For example, the sensing apparatus can investigate near-field (NF) and far-field (FF) regions of imaging light on the various object planes and apply adjustments (e.g., fine alignment), for example, by beam profiling (e.g., horizontal symmetry, vertical symmetry, etc.).

Light source apparatuses and systems as discussed below can reduce alignment times (e.g., SPM) of a master oscillator, reduce alignment variations in the master oscillator over time, and monitor and dynamically control quantifiable alignment errors of the master oscillator to provide a highly coherent light beam, for example, to a DUV lithographic apparatus.

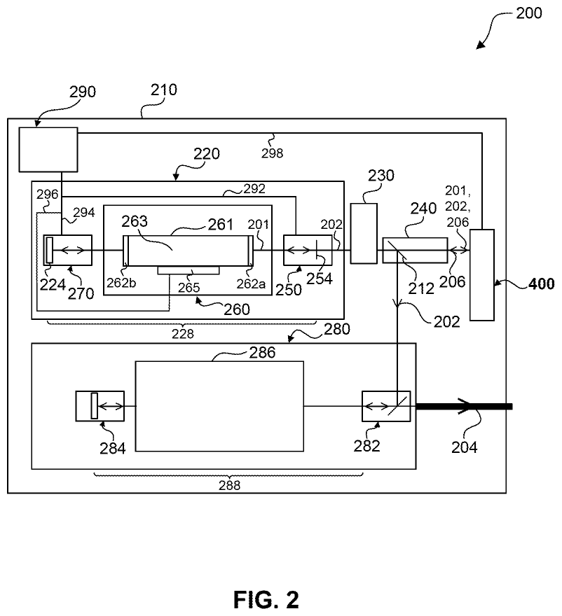

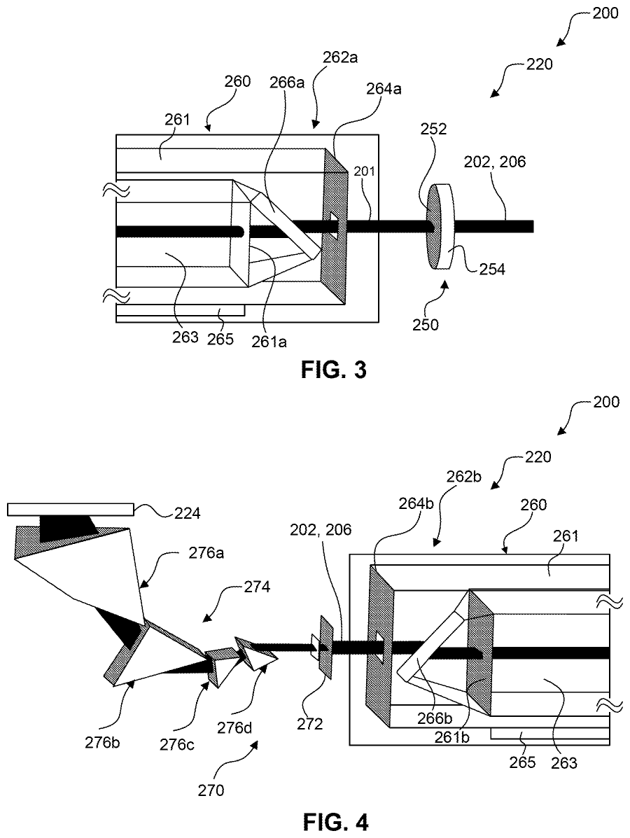

FIGS. 2-4 illustrate light source apparatus 200, according to various exemplary embodiments. FIG. 2 is a schematic top plan illustration of light source apparatus 200, according to an exemplary embodiment. FIGS. 3 and 4 are schematic partial cross-sectional illustrations of gas discharge stage 220 of light source apparatus 200 shown in FIG. 2, according to exemplary embodiments.

FIG. 2 illustrates light source apparatus 200, according to various exemplary embodiments. Light source apparatus 200 can be configured to monitor and dynamically control quantifiable alignment errors of gas discharge stage 220 (e.g., MO) and provide a highly coherent and aligned light beam (e.g., light beam 202, amplified light beam 204), for example, to a DUV lithographic apparatus (e.g., LA). Light source apparatus 200 can be further configured to reduce alignment times of gas discharge stage 220 (e.g., MO) and reduce alignment variations of gas discharge stage 220 (e.g., MO) over time. Although light source apparatus 200 is shown in FIG. 2 as a stand-alone apparatus and/or system, the embodiments of this disclosure can be used with other optical systems, such as, but not limited to, radiation source SO, lithographic apparatus LA, and/or other optical systems. In some embodiments, light source apparatus 200 can be radiation source SO in lithographic apparatus LA. For example, DUV radiation beam B can be light beam 202 and/or amplified light beam 204.

Light source apparatus 200 can be a MOPA formed by gas discharge stage 220 (e.g., MO) and power ring amplifier (PRA) stage 280 (e.g., PA). Light source apparatus 200 can include gas discharge stage 220, line analysis module (LAM) 230, master oscillator wavefront engineering box (MoWEB) 240, power ring amplifier (PRA) stage 280, and controller 290. In some embodiments, all of the above listed components can be housed in a three-dimensional (3D) frame 210. In some embodiments, 3D frame 210 can include a metal (e.g., aluminum, steel, etc.), a ceramic, and/or any other suitable rigid material.

Gas discharge stage 220 can be configured to output a highly coherent light beam (e.g., light beam 202). Gas discharge stage 220 can include first optical resonator element 254, second optical resonator element 224, input/output optical element 250 (e.g., OC), optical amplifier 260, and spectral feature adjuster 270 (e.g., LNM). In some embodiments, input/output optical element 250 can include first optical resonator element 254 and spectral feature adjuster 270 can include second optical resonator element 224. First optical resonator 228 can be defined by input/output optical element 250 (e.g., via first optical resonator element 254) and spectral feature adjuster 270 (e.g., via second optical resonator element 224). First optical resonator element 254 can be partially reflective (e.g., partial mirror) and second optical resonator element 224 can be reflective (e.g., mirror or grating) to form first optical resonator 228. First optical resonator 228 can direct light generated by optical amplifier 260 (e.g., amplified spontaneous emission (ASE) 201) into optical amplifier 260 for a fixed number of passes to form light beam 202. In some embodiments, as shown in FIG. 2, gas discharge stage 220 can output light beam 202 to PRA stage 280 as part of a MOPA arrangement.

PRA stage 280 can be configured to amplify light beam 202 from gas discharge stage 220 through a multi-pass arrangement and output amplified light beam 204. PRA stage 280 can include third optical resonator element 282, power ring amplifier (PRA) 286, and fourth optical resonator element 284. Second optical resonator 288 can be defined by third optical resonator element 282 and fourth optical resonator element 284. Third optical resonator element 282 can be partially reflective (e.g., partial beamsplitter) and fourth optical resonator element 284 can be reflective (e.g., mirror or prism or beam reverser) to form second optical resonator 288. Second optical resonator 288 can direct light beam 202 from gas discharge stage 220 into PRA 286 for a fixed number of passes to form amplified light beam 204. In some embodiments, PRA stage 280 can output amplified light beam 204 to a lithographic apparatus, for example, lithographic apparatus (LA). For example, amplified light beam 204 can be EUV and/or DUV radiation beam B from radiation source SO in lithographic apparatus LA.

As shown in FIGS. 2-4, optical amplifier 260 can be optically coupled to input/output optical element 250 and spectral feature adjuster 270. Optical amplifier 260 can be configured to output ASE 201 and/or light beam 202. In some embodiments, optical amplifier 260 can utilize ASE 201 as a beacon to guide boresighting of an optical axis of chamber 261 and/or an optical axis of gas discharge stage 220 (e.g., MO cavity). Optical amplifier 260 can include chamber 261, gas discharge medium 263, and chamber adjuster 265. Gas discharge medium 263 can be disposed within chamber 261, and chamber 261 can be disposed on chamber adjuster 265.

Chamber 261 can be configured to hold gas discharge medium 263 within first and second chamber optical ports 262a, 262b. Chamber 261 can include first chamber optical port 262a and second chamber optical port 262b opposite first chamber optical port 262a. In some embodiments, first and second chamber optical ports 262a, 262b can form an optical axis of chamber 261.

As shown in FIG. 3, first chamber optical port 262a can be in optical communication with input/output optical element 250. First chamber optical port 262a can include first chamber wall 261a, first chamber window 266a, and first chamber aperture 264a. In some embodiments, as shown in FIG. 3, first chamber aperture 264a can be a rectangular opening.

As shown in FIG. 4, second chamber optical port 262b can be in optical communication with spectral feature adjuster 270. Second chamber optical port 262b can include second chamber wall 261b, second chamber window 266b, and second chamber aperture 264b. In some embodiments, as shown in FIG. 4, second chamber aperture 264b can be a rectangular opening. In some embodiments, the optical axis of chamber 261 passes through first and second chamber apertures 264a, 264b.

Gas discharge medium 263 can be configured to output ASE 201 (e.g., 193 nm) and/or light beam 202 (e.g., 193 nm). In some embodiments, gas discharge medium 263 can include a gas for excimer lasing (e.g., Ar2, Kr2, F2, Xe2, ArF, KrCl, KrF, XeBr, XeCl, XeF, etc.). For example, gas discharge medium 263 can include ArF or KrF and, upon excitation (e.g., applied voltage) from surrounding electrodes (not shown) in chamber 261, output ASE 201 (e.g., 193 nm) and/or light beam 202 (e.g., 193 nm) through first and second chamber optical ports 262a, 262b. In some embodiments, gas discharge stage 220 can include a voltage power supply (not shown) configured to apply high voltage electrical pulses across electrodes (not shown) in chamber 261.

Chamber adjuster 265 can be configured to spatially adjust (e.g., laterally, angularly, etc.) an optical axis of chamber 261 (e.g., along first and second chamber optical ports 262a, 262b). As shown in FIG. 2, chamber adjuster 265 can be coupled to chamber 261 and first and second chamber optical ports 262a, 262b. In some embodiments, chamber adjuster 265 can have six degrees of freedom (e.g., 6-axes). For example, chamber adjuster 265 can include one or more linear motor(s) and/or actuator(s) providing adjustment of the optical axis of chamber 261 in six degrees of freedom (e.g., forward/back, up/down, left/right, yaw, pitch, roll). In some embodiments, chamber adjuster 265 can adjust chamber 261 laterally and angularly to align the optical axis of chamber 261 (e.g., along first and second chamber optical ports 262a, 262b) with an optical axis of gas discharge stage 220 (e.g., MO cavity). For example, as shown in FIG. 2, the optical axis of gas discharge stage 220 (e.g., MO cavity) can be defined by the optical axis of chamber 261 (e.g., along first and second chamber optical ports 262a, 262b), input/output optical element 250 (e.g., OC aperture 252), and spectral feature adjuster 270 (e.g., LNM aperture 272).

Input/output optical element 250 can be configured to be in optical communication with first chamber optical port 262a. In some embodiments, input/output optical element 250 can be an optical coupler (OC) configured to partially reflect a light beam and form first optical resonator 228. For example, OCs have been previously described in U.S. Pat. No. 7,885,309, issued Feb. 8, 2011, which is hereby incorporated by reference in its entirety. As shown in FIG. 2, input/output optical element 250 can include first optical resonator element 254 to direct (e.g., reflect) light into optical amplifier 260 and to transmit light (e.g., light beam 202, ASE 201) from optical amplifier 260 out of gas discharge stage 220 (e.g., MO cavity).

As shown in FIG. 3, input/output optical element 250 can include OC aperture 252 and first optical resonator element 254. First optical resonator element 254 can be configured to angularly adjust (e.g., tip and/or tilt) light through OC aperture 252 in vertical and/or horizontal directions relative to chamber 261 (e.g., first chamber optical port 262a). In some embodiments, OC aperture 252 can be a rectangular opening. In some embodiments, alignment of gas discharge stage 220 can be based on alignment of first chamber aperture 264a and OC aperture 252. In some embodiments, first optical resonator element 254 can adjust input/output optical element 250 angularly (e.g., tip and/or tilt) such that reflections from input/output optical element 250 are parallel to the optical axis of gas discharge stage 220 (e.g., MO cavity). In some embodiments, first optical resonator element 254 can be an adjustable mirror (e.g., partial reflector, beamsplitter, etc.) capable of angular adjustment (e.g., tip and/or tilt). In some embodiments, OC aperture 252 can be fixed and first optical resonator element 254 can be adjusted. In some embodiments, OC aperture 252 can be adjusted. For example, OC aperture 252 can be spatially adjusted in vertical and/or horizontal directions relative to chamber 261.

Spectral feature adjuster 270 (e.g., LNM) can be configured to be in optical communication with second chamber optical port 262b. In some embodiments, spectral feature adjuster 270 can be a line narrowing module (LNM) configured to provide spectral line narrowing to a light beam. For example, LNMs have been previously described in U.S. Pat. No. 8,126,027, issued Feb. 28, 2012, which is hereby incorporated by reference in its entirety.

As shown in FIG. 2, spectral feature adjuster 270 can include second optical resonator element 224 to direct (e.g., reflect) light (e.g., light beam 202, ASE 201) from optical amplifier 260 back into optical amplifier 260 toward input/output optical element 250.

As shown in FIG. 4, spectral feature adjuster 270 can include LNM aperture 272 and tilt angular modulator (TAM) 274. TAM 274 can be configured to angularly adjust light through LNM aperture 272 in vertical and/or horizontal directions relative to chamber 261 (e.g., second chamber optical port 262b). In some embodiments, LNM aperture 272 can be a rectangular opening. In some embodiments, alignment of gas discharge stage 220 can be based on alignment of second chamber aperture 264b and LNM aperture 272. In some embodiments, TAM 274 can adjust spectral feature adjuster 270 angularly (e.g., tip and/or tilt) such that reflections from spectral feature adjuster 270 are parallel to the optical axis of gas discharge stage 220 (e.g., MO cavity). In some embodiments, TAM 274 can include adjustable mirrors (e.g., partial reflector, beamsplitter, etc.) and/or adjustable prisms capable of angular adjustment (e.g., tip and/or tilt). In some embodiments, LNM aperture 272 can be fixed and TAM 274 can be adjusted. In some embodiments, LNM aperture 272 can be adjusted. For example, LNM aperture 272 can be spatially adjusted in vertical and/or horizontal directions relative to chamber 261.

In some embodiments, the adjustable mirrors (e.g., partial reflector, beamsplitter, etc.) and/or adjustable prisms of TAM 274 can include a plurality of prisms 276a-d. Prisms 276a-d can be actuated to manipulate an incident angle of incoming light on second optical resonator element 224, which can serve to select a narrow band of wavelength to reflect back along the optical path. In some embodiments, prism 276a can be fitted with a stepper motor with limited step resolution and can be used for coarse wavelength control. Prism 276b may be actuated using a piezoelectric transducer (PZT) actuator, which provides for improved resolution and bandwidth in comparison to prism 276a. In operation, controller 290 can use prisms 276a, 276b in a dual-stage configuration.

LAM 230 can be configured to monitor a line center (e.g., center wavelength) of a light beam (e.g., light beam 202, imaging light 206). LAM 230 can be further configured to monitor an energy of a light beam (e.g., ASE 201, light beam 202, imaging light 206) for metrology wavelength measurements. For example, LAMs have been previously described in U.S. Pat. No. 7,885,309, issued Feb. 8, 2011, which is hereby incorporated by reference in its entirety.

As shown in FIG. 2, LAM 230 can be optically coupled to gas discharge stage 220 and/or MoWEB 240. In some embodiments, LAM 230 can be disposed between gas discharge stage 220 and MoWEB 240. For example, as shown in FIG. 2, LAM 230 can be optically coupled directly to MoWEB 240 and optically coupled to gas discharge stage 220. In some embodiments, as shown in FIG. 2, beamsplitter 212 can be configured to direct ASE 201 and/or light beam 202 toward PRA stage 280, and direct ASE 201 and/or light beam 202 toward an imaging apparatus. In some embodiments, as shown in FIG. 2, beamsplitter 212 can be disposed in MoWEB 240.

MoWEB 240 can be configured to provide beam shaping to a light beam (e.g., light beam 202, imaging light 206). MoWEB 240 can be further configured to monitor forward and/or backward propagation of a light beam (e.g., ASE 201, light beam 202, imaging light 206). For example, MoWEBs have been previously described in U.S. Pat. No. 7,885,309, issued Feb. 8, 2011, which is hereby incorporated by reference in its entirety. As shown in FIG. 2, MoWEB 240 can be optically coupled to LAM 230. In some embodiments, LAM 230, MoWEB 240, and/or imaging apparatus can be optically coupled to gas discharge stage 220 via a single optical arrangement.

Controller 290 can be configured to be in communication with input/output optical element 250, chamber adjuster 265, and/or spectral feature adjuster 270. In some embodiments, controller 290 can be configured to provide first signal 292 to input/output optical element 250, second signal 294 to spectral feature adjuster 270, and third signal 296 to chamber adjuster 265. In some embodiments, controller 290 can be configured to provide a signal (e.g., first signal 292 and/or second signal 294) to input/output optical element 250 and/or spectral feature adjuster 270 and adjust input/output optical element 250 (e.g., adjust first optical resonator element 254) and/or spectral feature adjuster 270 (e.g., adjust TAM 274) based on an output (e.g., two-dimensional (2D) image comparison) from imaging apparatus 400.

In some embodiments, first optical resonator element 254, chamber adjuster 265, and/or TAM 274 can be in physical and/or electronic communication with controller 290 (e.g., first signal 292, second signal 294, and/or third signal 296). For example, first optical resonator element 254, chamber adjuster 265, and/or TAM 274 can be adjusted (e.g., laterally and/or angularly) by controller 290 to align the optical axis of chamber 261 (e.g., along first and second chamber optical ports 262a, 262b) with the optical axis of gas discharge stage 220 (e.g., MO cavity) defined by input/output optical element 250 (e.g., OC aperture 252) and spectral feature adjuster 270 (e.g., LNM aperture 272).

During normal operation, a laser wavelength may be subject to disturbances and drift as optics go through thermal transients and as a laser duty cycle changes. The primary wavelength actuator is the LNM. As discussed above, the LNM may include the plurality of prisms 276a-d and the second optical resonator element 224 (e.g., a grating). The plurality of prisms 276a-d may be actuated to manipulate an incoming light's incident angle on the second optical resonator element 224, which serves to select a narrow band of wavelength to reflect back along the optical path. In some embodiments, a magnitude of the incident angle may control the wavelength selected.

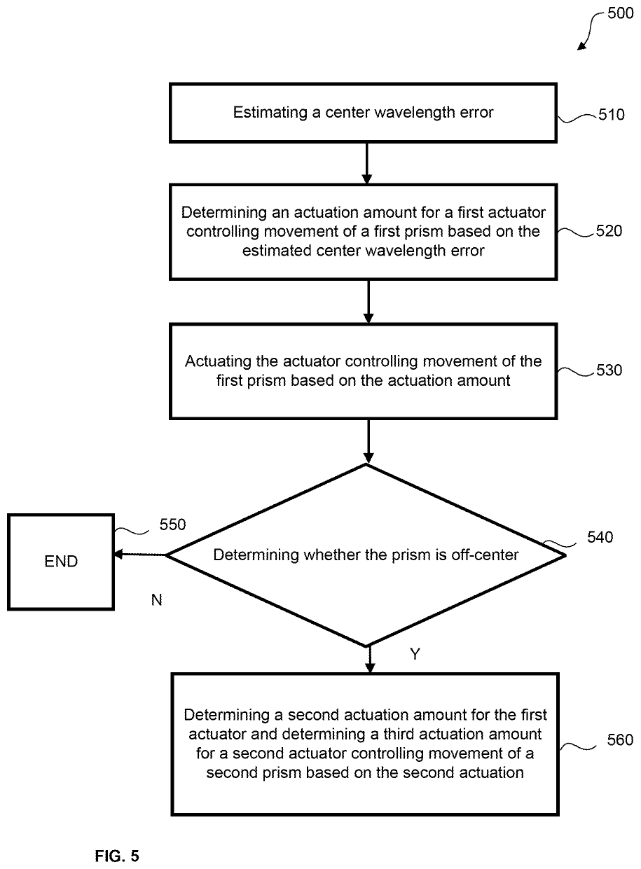

In some embodiments, to control the magnitude of the incident angle, and consequently, the wavelength selected, the plurality of prisms 276a-d may be used to adjust the final incident angle. For example, prism 276a may have more control over the final incident angle than the 276b. That is, in some embodiments, the controller 290 uses prisms 276a, 276b in a dual-stage configuration, with prism 276a being used for large jumps and to desaturate prism 276b, which is used for finer changes to the final incident angle. Controlling prisms 276a, 276b is of particular important for MFI operations, which require more than regulation around a setpoint, and instead, require precise tracking of a sinusoid at Nyquist frequency in addition to precise control of the center point of the sinusoid (i.e., the central wavelength). The processes described with respect to FIGS. 5, 6A, 6B, and 7-9 provide method for controlling the central wavelength for imaging operations, such as MFI operations.

Multi-focal imaging operations may include a two-color mode. Operating the light source in the two-color mode may include: generating, using a first laser chamber module, a first beam of laser radiation at a first wavelength; generating, using a second laser chamber module, a second beam of laser radiation at a second wavelength; and combining, using a beam combiner, the first and second laser radiations along a common output beam path. In the two-color mode, a wavelength target may alternate between two known setpoints within a burst (e.g., every pulse), and the PZT may be used in order to track the fast-changing target that leaves little margin to control the center wavelength.

FIG. 5 illustrates a method 500 for adjusting a center wavelength for multi-focal or other imaging, according to an embodiment. It is to be appreciated that not all steps in FIG. 5 are needed to perform the disclosure provided herein. Further, some of the steps can be performed simultaneously, sequentially, and/or in a different order than shown in FIG. 5. Method 500 shall be described with reference to FIGS. 1-4. However, method 500 is not limited to those example embodiments.

In some embodiments, method 500 is directed to formulating a feedback loop to regulate the center wavelength of a beam of laser radiation, by moving actuators for respectively controlling movement of prisms 276a and 276b based on an average center wavelength error evaluated from LAM 230. To achieve this, a center wavelength of the most recent pulse can be estimated using LAM data. In some embodiments, a difference between a target center wavelength and the estimated center wavelength can be provided to controller 290 to determine a desired actuation for prism 276b to compensate for disturbances on the center wavelength. As prism 276b has limited traveling range, controller 290 can also ensure prism 276b is centered by actuating prism 276b as needed.

At 510, method 500 can include estimating a center wavelength error. For example, the center wavelength error can be estimated based on a first average of the center wavelength at odd bursts and a second average of the center wavelength at even bursts, and determining a third average based on the first and second averages. In some embodiments, the center wavelength error may be based on the difference between the center wavelength and the third average.

At 520, method 500 can include determining an actuation amount for a first actuator that controls movement of prism 276b based on the estimated center wavelength. For example, controller 290 of FIG. 2 can determine a difference between a target center wavelength and the estimated wavelength, and determine how much to actuate the actuator controlling movement of prism 276b to compensate for the difference. At 530, method 500 can include actuating the actuator that controls movement of prism 276b based on the actuation amount.

At 540, method 500 can include determining whether prism 276b is off-center. In response to determining that prism 276b is centered, the method 500 ends at 550. In response to determining that prism 276b is off-center, at 560, method 500 can include determining a second actuation amount for the actuator controlling movement of prism 276b and determining a third actuation amount for a second actuator controlling movement of prism 276a based on the second actuation of the first actuator. That is, controller 290 can determine how much actuation is required for both prisms 276a, 276b to remedy the center wavelength error.

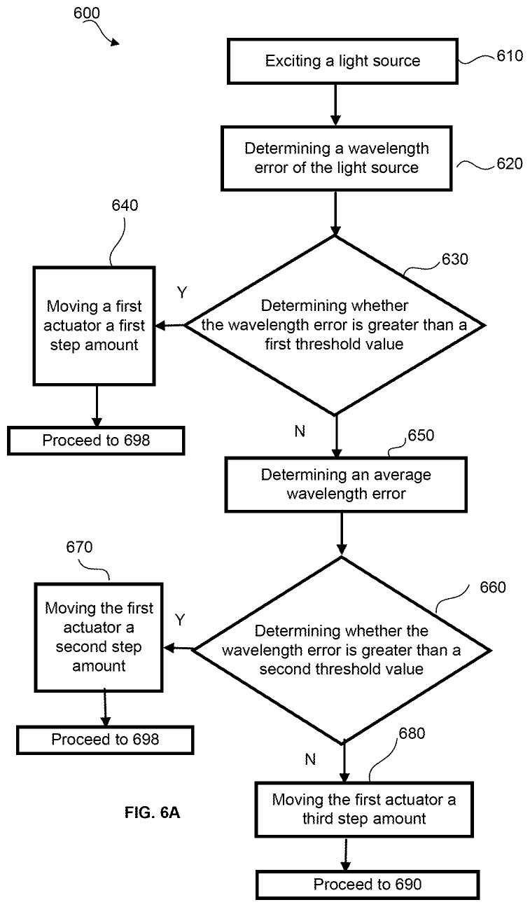

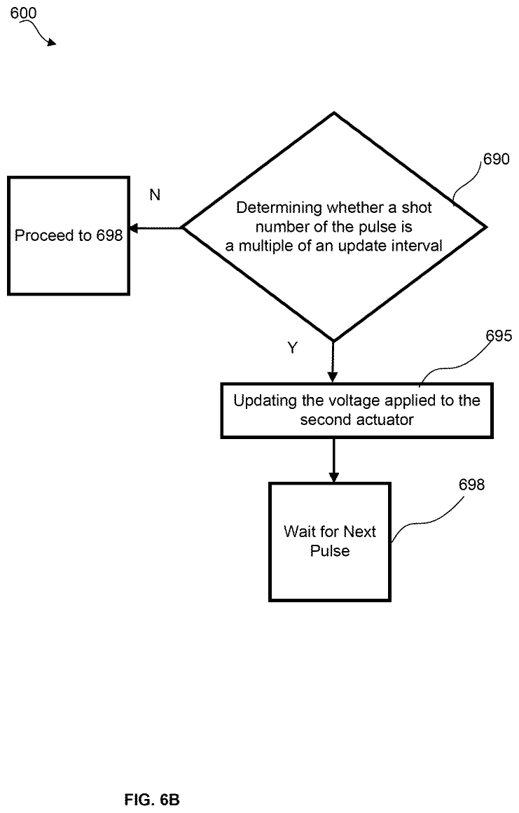

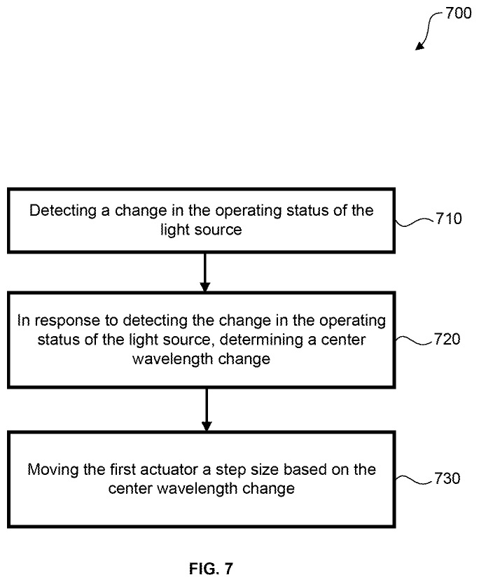

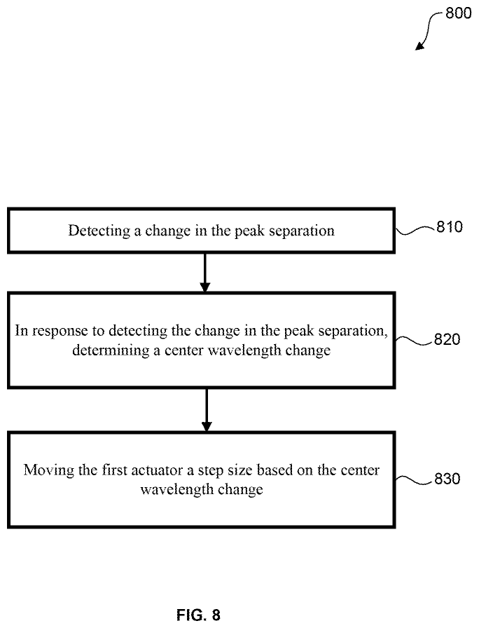

FIGS. 6A-B, 7, and 8 illustrate methods for adjusting a center wavelength for an imaging operation such as multi-focal imaging, according to some embodiments. It is to be appreciated that not all steps in FIGS. 6-8 are needed to perform the disclosure provided herein. Further, some of the steps can be performed simultaneously, sequentially, and/or in a different order than shown in FIGS. 6A-B, 7, and 8. These methods shall be described with reference to FIGS. 1-4. However, these methods are not limited to those example embodiments.

FIGS. 6A-B, 7, and 8 are directed to methods for regulating a center wavelength of a beam of laser radiation such as in a two-color MFI mode. The two-color MFI mode may encounter challenges, such as prism 276b having little margin in the two-color mode for center wavelength control, step disturbances from mode transitions, and/or peak separation changes can cause a transient if handled using pure feedback, and a center wavelength controller can interact with other controller(s), e.g. a peak separation controller, which can lead to degraded performance or even instability. To address these challenges, in some embodiments, prism 276a can be moved within a burst to compensate for large center wavelength errors, while limiting movement of prism 276b to compensate for small and low-pass-filtered errors. Furthermore, in some embodiments, prism 276a can be moved to de-saturate prism 276b. In some embodiments, prism 276a can be moved outside of a burst upon detecting two-color mode transitions or peak separation target changes. In some embodiments, control bandwidths between the center wavelength controller and other controllers, e.g., a peak separation controller, can be separated from one another.

As illustrated in FIGS. 6A-B, at 610, method 600 can include exciting a light source such as a laser chamber in an MFI system. At 620, method 600 can include determining a wavelength error of the light source, which may be either a first beam of laser radiation at a first wavelength from a first laser chamber module or a second beam of laser radiation at a second wavelength generated using a second laser chamber module. In some embodiments, determining the wavelength error can include measuring a central wavelength of a light beam generated by the light source and determining a difference between the central wavelength and a target center wavelength.

At 630, method 600 can include determining whether the wavelength error is greater than a first threshold value. For example, the threshold value can be 200 femtometers. It should be understood by those of ordinary skill in the arts that this is merely an example threshold value, and that other threshold values are further contemplated in accordance with aspects of the present disclosure.

In some embodiments, at 640, in response to determining that the wavelength error is greater than the threshold value, method 600 can include moving a first actuator for controlling movement of prism 276a. For example, the first actuator can be moved a first step size every pulse while a filter, such as a low pass filter, and movement of a second actuator for controlling movement of prism 276b are disabled. For example, the first actuator can be moved in a direction that reduces the wavelength error. The first step size can be a fixed step size, such as one full step of the first actuator. By moving the first actuator while the filter and second actuator are disabled, method 600 provides for gross changes to the wavelength error and de-saturates prism 276b. In some embodiments, after the first actuator is moved the first step, at 698, method 600 concludes with waiting for a next pulse of the light source.

In some embodiments, at 650, in response to determining that the wavelength error is less than the first threshold value, method 600 can include determining an average wavelength error. In some embodiments, the average wavelength error may be a moving average based on a low-pass filtering technique, as should be understood by those of ordinary skill in the art. At 660, method 600 can include determining whether the average wavelength error is greater than a second threshold value. In some embodiments, the second threshold value may different than the first threshold value. For example, the second threshold value can be 100 femtometers. It should be understood by those of ordinary skill in the arts that this is merely an example threshold value, and that other threshold values are further contemplated in accordance with aspects of the present disclosure. In some embodiments, the average wavelength error can be based on the wavelength error and an average of a plurality of wavelength errors over a number of pulses n, with n being the number of pulses greater than one (1). That is, the average wavelength error can be a moving average of the wavelength error.

In some embodiments, at 670, in response to determining that the average wavelength error is greater than the second threshold value, method 600 can include moving the first actuator with a second step size, enabling the low pass filter, and disabling movement of the second actuator. For example, the first actuator can be moved in a direction that reduces the wavelength error. In some embodiments, the second step size can be proportional to the wavelength error, e.g., the smaller the average wavelength error, the smaller the step size for the first actuator, and vice-versa. In some embodiments, the second step size may be less than a full step size. In some embodiments, the second step size may be greater than the full step size. By moving the first actuator a step size proportional to the average wavelength error, method 600 prevents overshooting a desired position of the prism 276a. In some embodiments, after the first actuator is moved the second step, at 698, method 600 concludes with waiting for a next pulse of the light source.

In some embodiments, at 680, in response to determining that the average wavelength error is less than the second threshold value, method 600 can include moving the first actuator with a third step size. In some embodiments, the third step size can be proportional to a voltage applied to the second actuator and resetting the voltage applied to the second actuator. Thus, in some embodiments, the third step size can be based on the voltage applied to the second actuator, rather than the average wavelength error.

In some embodiments, at 690, method 600 can include determining whether a shot number of the pulse is a multiple of an update interval. A shot number can be, for example, a number of a pulse of the light beam. In some embodiments, the update interval can be, for example, every five (5) or ten (10) pulses. It should be understood by those of ordinary skill in the arts that these are merely example update intervals, and that other update intervals are further contemplated in accordance with aspects of the present disclosure. That is, in some embodiments, method 600 can include determining whether the pulse is, for example, the fifth or tenth pulse. In some embodiments, when the shot number is not equal to the update interval, at 698, method 600 concludes with waiting for a next pulse of the light source.

In some embodiments, when the shot number is equal to the update interval, at 695, method 600 can include updating the voltage applied to the second actuator. For example, the voltage applied to the second actuator can be based on the average wavelength error, such that movement of the prism 276b accommodates for the average wavelength error in subsequent pulses. In some embodiments, after updating the voltage applied to the second actuator, at 698, method 600 concludes with waiting for a next pulse of the light source.

In some embodiments, method 700 of FIG. 7 can be executed between pulses of the light source. During this period, the light source can transition between operating modes, e.g., between a single-color mode and a two-color mode, and as a result, the center wavelength can change due to the change in operating status. To address this, as shown in FIG. 7, method 700 can also include, at 710, detecting a change in the operating status of the light source. At 720, in response to detecting the change in the operating status of the light source, method 700 can include determining a center wavelength change. For example, determining the center wavelength change can include determining a midpoint of a target peak separation. At 730, method 700 can include moving the first actuator a step size based on the center wavelength change. In some embodiments, the processes described with respect to FIG. 7 can be performed between bursts of the light source. By doing so, method 700 provides for reducing wavelength errors the next time the light source is activated.

In some embodiments, method 800 of FIG. 8 can be executed between pulses of the light source. During this period, a target peak separation can change. To address this, as shown in FIG. 8, method 800 can include, at 810, detecting a change in the peak separation. At 820, in response to detecting the change in the peak separation, method 800 can also include determining a center wavelength change. For example, determining the center wavelength change can include determining an average between a previous peak separation target and a new peak separation target. At 830, method 800 can include moving the first actuator a step size based on the center wavelength change. In some embodiments, the processes described with respect to FIGS. 7 and 8 can be performed between bursts of the light source. By doing so, methods 700 and 800 provide for reducing wavelength errors the next time the light source is activated. Additionally, using the processes described in FIGS. 7 and 8, the present disclosure reduces the number of bursts required to complete the transition between the different operating modes.

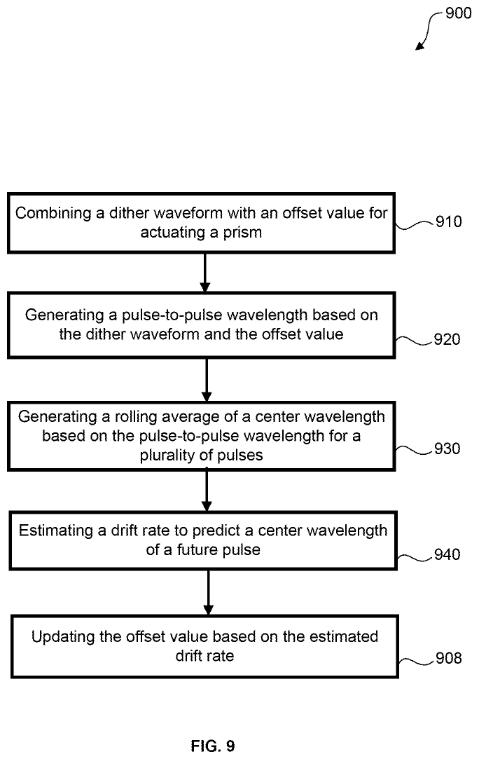

FIG. 9 illustrates method 900 for adjusting a center wavelength such as may be used for multi-focal imaging, according to an embodiment. It is to be appreciated that not all steps in FIG. 9 are needed to perform the disclosure provided herein. Further, some of the steps can be performed simultaneously, sequentially, and/or in a different order than shown in FIG. 9. Method 900 shall be described with reference to FIGS. 1-4. However, method 900 is not limited to those example embodiments.

In some embodiments, the processes discussed with respect to FIG. 9 provide for moving an actuator controlling movement of prism 276b during the burst. That is, the processes discussed with respect to FIG. 9 provide for an instar-burst solution for addressing a change to the center wavelength such as may be from either a first beam of laser radiation at a first wavelength from a first laser chamber module or a second beam of laser radiation at a second wavelength generated using a second laser chamber module in MFI mode. To achieve this, in some embodiments, the processes described with respect to FIG. 9 estimate a drift rate of the center wavelength in order to compensate for measurement delays of the center wavelength.

In some embodiments, a dither waveform (or sequence) can be combined with an offset for moving an actuator for prism 276b. For example, the dither waveform may be an applied form of noise used to randomize quantization. The offset can be updated at an end-of-burst (EOB) and/or at a set pulse interval. In some embodiments, the EOB update can move the actuator for prism 276b to zero out the estimated center wavelength drift obtained by averaging the wavelength measurements of the entire burst. In some embodiments, the interval updates can be based on the estimation processes described herein. In some embodiments, the estimation processes described herein can be based on a rolling average estimate of center wavelength up to the current pulse and can be provided access to both the offset for the actuator for prism 276b and a second offset for the actuator for prism 276a. In other words, in some embodiments, the processes for estimating the drift rate can be based on current positions of prisms 276a, 276b, as well at the respective offsets for each actuator, and the rolling average of the center wavelength, and estimating a total accumulated center wavelength drift using a Kalman filter framework. In some embodiments, to compensate for delay of LAM 230, a drift two shots ahead can be predicted by converting a Kalman filter into a Kalman predictor. That is, by using known inputs and any disturbances, the drift rate can be estimated using an open-loop propagation to predict the drift rate two steps ahead of a current burst.

In some embodiments, the Kalman filter can be modeled using Equations 1 and 2. In some embodiments, at any given point, the center wavelength with respect to the center wavelength target can be based on the sum of the positions of the prisms 276a, 276b, scaled by appropriate gains, and an accumulated wavelength drift D(k) at time k. In some embodiments, the accumulated wavelength drift can be modeled as a linear drift with an unknown rate at time k defined as DSR(k). As a result, the drift rate can vary over time without issue and can be incorporated into the state vector thereby allowing the drift rate to be estimated.

$$[ \begin{matrix}CWL ( k + 1 ) \\ D ( k + 1 ) \\ DSR ( k + 1 )\end{matrix} ] = [ \begin{matrix}0 & 1 & 0 \\ 0 & 1 & 1 \\ 0 & 0 & 1\end{matrix} ] [ \begin{matrix}CWL ( k ) \\ D ( k ) \\ DSR ( k )\end{matrix} ] + [ \begin{matrix}115. & 20.4 \\ 0 & 0 \\ 0 & 0\end{matrix} ] [ \begin{matrix}P 3 offset \\ P 4 offset\end{matrix} ] ( = {Ax}_{k} + {Bu}_{k} ) \qquad ( 1 )$$

$$y ( k ) = [ \begin{matrix}1 & 0 & 0\end{matrix} ] [ \begin{matrix}CWL ( k ) \\ D ( k ) \\ DSR ( k )\end{matrix} ] + 0 [ \begin{matrix}P 3 offset \\ P 4 offset\end{matrix} ] ( = {Cx}_{k} + {Du}_{k} ) \qquad ( 2 )$$

With the model constructed thusly, the steady-state Kalman filter can be implemented as in Equation 3, with A, B, C, and D being defined in Equations 1 and 2, Q and R being tuning parameters, and S being the solution to the Algebraic Ricatti Equation given in Equation 4.

\hat{x}(k+1)=A\hat{x}(k)+Bu(k)+R⁻¹B^{T}S(tmpCenterWL(k)−C\hat{x}(k−1)) (3)

AS+SA^{T}−SC^{T}R⁻¹CS+Q=0 (4)

In some embodiments, a controller, e.g., controller 290, can be provided with the total accumulated drift and the estimated drift rate, such that the changes to the center wavelength can be compensated for.

In some embodiments, the offset P3_{offset} can be defined using as in Equation 5. By using to known inputs and any disturbances incorporated into the model, the drift rate can be estimated using an open-loop propagation of the model two steps ahead.

$$P 3 offset ( k ) = [ \begin{matrix}0 & \frac{1}{115} & 0\end{matrix} ] {A}^{2} \hat{x} ( k ) \qquad ( 5 )$$

Based on the foregoing, the drift rate can estimated based on wavelength measurements in real-time. The drift rate can be used to predict a magnitude of a wavelength drift and to compensate for it shot-to-shot. In some embodiments, the drift rate can be modeled as an accumulator with a variable rate of accumulation and a Kalman filter can be used to estimate the accumulation rate based on an estimate of center wavelength (e.g., the arithmetic mean of all wavelength measurements in the current burst).

In some embodiments, to compensate for measurement delay(s) in LAM 230, the center wavelength N pulses, e.g., two pulses, ahead can be predicted and used to determine the offset applied to the actuator for the prism 276b. For example, in some embodiments, N pulses may be two pulses, although it should be understood by those ordinary skill in the art that this is merely an example number of pulses, and that more or less pulses are contemplated in accordance with aspects of the present disclosure. In some embodiments, this offset can be updated shot-to-shot, at sub-femtometer resolution.

At 910, method 900 can include combining a dither waveform with an offset value for actuating a prism. In some embodiments, the offset value can be used to move an actuator for controlling movement of prism 276b. In some embodiments, the offset value is based on a direct current (DC) voltage applied to the actuator for controlling movement of prism 276b. In some embodiments, an initial value of the DC voltage is zero volts.

At 920, method 900 can include generating a pulse-to-pulse wavelength based on the dither waveform and the offset value. For example, the pulse-to-pulse wavelength can be generated using LAM 230. In some embodiments, the pulse-to-pulse wavelength can also be based on other disturbances from within the lithographic apparatus LA.

At 930, method 900 can include generating a rolling average of a center wavelength based on the pulse-to-pulse wavelength for a plurality of pulses. In some embodiments, the pulse-to-pulse wavelength for the plurality of pulses includes a wavelength of a current pulse.

At 940, method 900 can include estimating a drift rate to predict a center wavelength of a future pulse. In some embodiments, the offset value for moving the actuator associated with prism 276b can be a first offset value, and estimating the drift rate can include estimating the drift rate based on the rolling average of the center wavelength, the first offset value, and a second offset value moving a second actuator controlling movement of a second prism 276a. In some embodiments, estimating the drift rate comprises estimating an accumulated center wavelength drift rate using a Kalman filter framework. For example, the Kalman filter framework can estimate the accumulated center wavelength drift rate based on the rolling average of the center wavelength, the first offset value, and the second offset value. Additionally, estimating the drift rate can include predicting the center wavelength N pulses, e.g., two pulses, ahead of a current pulse. To achieve this, the Kalman filter framework can be converted into a Kalman predictor to predict the center wavelength N pulses, e.g., two pulses, ahead of the current pulse.

At 950, method 900 can include updating the offset value based on the estimated drift rate. In some embodiments, updating the offset value can also be based on the rolling average of the center wavelength at an end of a burst, in addition to the estimated drift rate.

Example Computer System

Various embodiments and components therein can be implemented, for example, using one or more well-known computer systems, such as, for example, the example embodiments, systems, and/or devices shown in the figures or otherwise discussed. Computer system 1000 can be any well-known computer capable of performing the functions described herein.

Computer system 1000 includes one or more processors (also called central processing units, or CPUs), such as a processor 1004. Processor 1004 is connected to a communication infrastructure or bus 1006.

One or more processors 1004 may each be a graphics processing unit (GPU). In an embodiment, a GPU is a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 1000 also includes user input/output device(s) 1003, such as monitors, keyboards, pointing devices, etc., that communicate with communication infrastructure 1006 through user input/output interface(s) 1002.

Computer system 1000 also includes a main or primary memory 1008, such as random access memory (RAM). Main memory 1008 may include one or more levels of cache. Main memory 1008 has stored therein control logic (i.e., computer software) and/or data.

Computer system 1000 may also include one or more secondary storage devices or memory 1010. Secondary memory 1010 may include, for example, a hard disk drive 1012 and/or a removable storage device or drive 1014. Removable storage drive 1014 may be a floppy disk drive, a magnetic tape drive, a compact disk drive, an optical storage device, tape backup device, and/or any other storage device/drive.

Removable storage drive 1014 may interact with a removable storage unit 1018. Removable storage unit 1018 includes a computer usable or readable storage device having stored thereon computer software (control logic) and/or data. Removable storage unit 1018 may be a floppy disk, magnetic tape, compact disk, DVD, optical storage disk, and/any other computer data storage device. Removable storage drive 1014 reads from and/or writes to removable storage unit 1018 in a well-known manner.

According to an example embodiment, secondary memory 1010 may include other means, instrumentalities or other approaches for allowing computer programs and/or other instructions and/or data to be accessed by computer system 1000. Such means, instrumentalities or other approaches may include, for example, a removable storage unit 1022 and an interface 1020. Examples of the removable storage unit 1022 and the interface 1020 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 1000 may further include a communication or network interface 1024. Communication interface 1024 enables computer system 1000 to communicate and interact with any combination of remote devices, remote networks, remote entities, etc. (individually and collectively referenced by reference number 1028). For example, communication interface 1024 may allow computer system 1000 to communicate with remote devices 1028 over communications path 1026, which may be wired and/or wireless, and which may include any combination of LANs, WANs, the Internet, etc. Control logic and/or data may be transmitted to and from computer system 1000 via communications path 1026.

In an embodiment, a non-transitory, tangible apparatus or article of manufacture comprising a non-transitory, tangible computer useable or readable medium having control logic (software) stored thereon is also referred to herein as a computer program product or program storage device. This includes, but is not limited to, computer system 1000, main memory 1008, secondary memory 1010, and removable storage units 1018 and 1022, as well as tangible articles of manufacture embodying any combination of the foregoing. Such control logic, when executed by one or more data processing devices (such as computer system 1000), causes such data processing devices to operate as described herein.

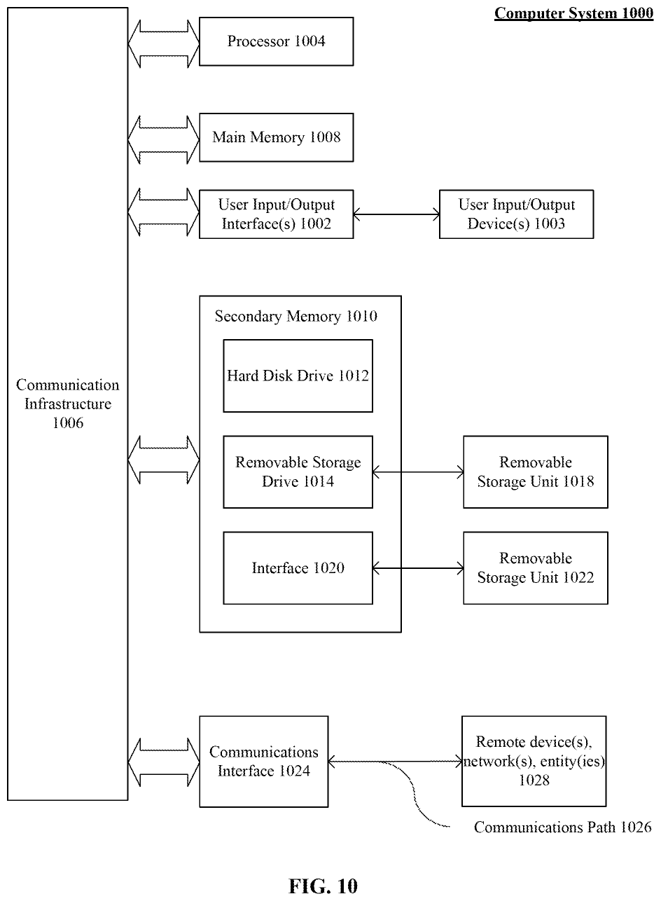

Based on the teachings contained in this disclosure, it will be apparent to persons skilled in the relevant art(s) how to make and use embodiments of this disclosure using data processing devices, computer systems and/or computer architectures other than that shown in FIG. 10. In particular, embodiments may operate with software, hardware, and/or operating system implementations other than those described herein.

Although specific reference may have been made above to the use of embodiments in the context of optical lithography, it will be appreciated that embodiments may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some embodiments, the substrate itself may be patterned and materials added on top of it may also be patterned, or may remain without patterning.

The following examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments have been described above, it will be appreciated that the embodiments may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the embodiments and the appended claims in any way.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the embodiments. Therefore, such adaptations and modifications are intended to be within the meaning and range of equivalents of the disclosed embodiments, based on the teaching and guidance presented herein.

Other aspects of the invention are set out in the following numbered clauses.

1. A method for controlling a center wavelength for an imaging operation, comprising: estimating a center wavelength error;
determining a first actuation amount for a first actuator controlling movement of a first prism based on the estimated center wavelength error;
actuating the first actuator based on the first actuation amount;
determining whether the first prism is off-center;
in response to determining that the first prism is off-center, determining a second actuation amount for the first actuator and determining a third actuation amount for a second actuator for controlling movement of a second prism; and
actuating the first actuator and the second actuator based on the second and third actuation amounts, respectively.
2. The method of clause 1, wherein the estimating the center wavelength error comprises: calculating a first average of a center wavelength at odd bursts and a second average of the center wavelength at even bursts; and
determining an average of the first and second averages, wherein the center wavelength error is based on the average of the first and second averages.
3. The method of clause 1, wherein the determining the first actuation amount comprises: determining a difference between a target center wavelength and the estimated center wavelength; and determining the first actuation amount based on the difference between the target center wavelength and the estimated center wavelength.
4. The method of clause 3, wherein the determining the difference between the target center wavelength and the estimated center wavelength comprises determining the difference using a digital filter.
5. The method of clause 1, wherein the determining the third actuation amount for the second actuator is based on a position of the first prism after actuating the first actuator based on the second actuation amount.
6. The method of clause 5, wherein the determining the third actuation amount further comprises determining the third actuation amount to reduce the difference between the target center wavelength and the estimated wavelength.
7. The method of clause 1, wherein the imaging operation comprises a multi-focal imaging operation, and the method further comprises operating a light source in a two-color mode, wherein operating the light source in the two-color mode includes:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the estimating a center wavelength error comprises estimating a center wavelength error of the first beam of laser radiation.
8. A method for controlling a center wavelength, comprising:
determining a wavelength error of a light beam generated by a light source;
determining whether the wavelength error is greater than a first threshold value;
in response to determining that the wavelength error is greater than the first threshold value, moving a first actuator a first step size, the first actuator being configured to control movement of a first prism;
in response to determining that the wavelength error is less than the first threshold value: determining an average wavelength error;
determining whether the average wavelength error is greater than a second threshold value different than the first threshold value;
in response to determining that the average wavelength error is greater than the second threshold value, moving the first actuator a second step size and enabling a low pass filter; and
in response to determining that the average wavelength error is less than the second threshold value, enabling the low pass filter, updating a voltage applied to a second actuator, and moving the first actuator a third step size, the second actuator being configured to control movement of a second prism.
9. The method of clause 8, wherein the determining the wavelength error comprises:
measuring a central wavelength of the light beam generated by the light source; and determining a difference between the central wavelength and a target center wavelength.
10. The method of clause 8, further comprising:
determining whether a shot number of a pulse of the light source is a multiple of an update interval; and in response to determining that the shot number is equal to the update interval, updating the voltage applied to the second actuator.
11. The method of clause 8, further comprising disabling the low pass filter and movement of a second actuator in response to determining that the wavelength error is greater than the first threshold value.
12. The method of clause 8, wherein the first step size is a fixed step size of the actuator.
13. The method of clause 8, wherein the second step size is a function of the wavelength error.
14. The method of clause 8, wherein the third step size is a function of the voltage applied to second actuator.
15. The method of clause 8, wherein the moving the first actuator with the second step size comprises moving the first actuator every n pulses, with n being greater than one.
16. The method of clause 8, wherein the average wavelength error is based on the wavelength error and an average of a plurality of wavelength errors over a number of pulses.
17. The method of clause 8, wherein the method comprises controlling the center wavelength in a multi-focal imaging operation, and the method further comprises operating a light source in a two-color mode, wherein operating the light source in the two-color mode comprises:
generating, using a first laser chamber module, a first beam of laser radiation at a first wavelength; generating, using a second laser chamber module, a second beam of laser radiation at a second wavelength; and
combining, using a beam combiner, the first and second laser radiations along a common output beam path,
wherein the determining the wavelength error of the light beam generated by the light source comprises determining a center wavelength error of the first beam of laser radiation.
18. A method for controlling a center wavelength for a multi-focal imaging operation, comprising:
combining a dither waveform with an offset value for moving an actuator controlling movement of a prism;
generating a pulse-to-pulse wavelength based on the dither waveform and the offset value;
generating a rolling average of the center wavelength based on the pulse-to-pulse wavelength for a plurality of pulses;
estimating a drift rate to predict a center wavelength of a future pulse; and
updating the offset value based on the estimated drift rate.
19. The method of clause 18, wherein the offset value is based on a direct current (DC) voltage.
20. The method of clause 19, wherein an initial value of the DC voltage is zero volts.
21. The method of clause 18, wherein:
the offset value comprises a first offset value, and
the estimating the drift rate comprises estimating the drift rate based on the rolling average of the center wavelength, the first offset value, and a second offset value moving a second actuator controlling movement of a second prism.
22. The method of clause 21, wherein the estimating the drift rate comprises estimating an accumulated center wavelength drift rate using a Kalman filter framework.
23. The method of clause 22, wherein the estimating the drift rate comprises predicting the center wavelength N pulses ahead of a current pulse.
24. The method of clause 23, wherein the estimating the drift rate comprises converting the Kalman filter framework into a Kalman predictor to predict the center wavelength N pulses ahead of the current pulse.
25. The method of clause 18, wherein the pulse-to-pulse wavelength for a plurality of pulses comprises a wavelength of a current pulse.
26. The method of clause 18, wherein the updating the offset value further comprises updating the offset value based on the rolling average of the center wavelength at an end of a burst.
27. A system comprising:
a first actuator configured to control movement of a first prism;
a second actuator configured to control movement of a second prism; and
a controller configured to:
estimate a center wavelength error;
determine a first actuation amount for the first actuator based on the estimated center wavelength error;
cause the first actuator to actuate based on the first actuation amount;
determine whether the first prism is off-center;
in response to determining that the first prism is off-center, determine a second actuation amount for the first actuator and determine a third actuation amount for the second actuator; and
cause the first and second actuators to actuate based on the second and third actuation amounts, respectively.
28. The system of clause 27, wherein, to estimate the center wavelength error, the controller is further configured to:
calculate a first average of a center wavelength at odd bursts and a second average of the center wavelength at even bursts; and
determine an average of the first and second averages, wherein the center wavelength error is based on the average of the first and second averages.
29. The system of clause 27, wherein to determine the first actuation amount, the controller is further configured to:
determine a difference between a target center wavelength and the estimated center wavelength; and determine the first actuation amount based on the difference between the target center wavelength and the estimated center wavelength.
30. The system of clause 29, wherein to determine the difference between the target center wavelength and the estimated center wavelength, the controller is further configured to determine the difference using a digital filter.
31. The system of clause 27, wherein the third actuation amount for the second actuator is based on a position of the first prism after actuating the first actuator based on the second actuation amount.
32. The system of clause 31, wherein, to determine the third actuation amount, the controller is further configured to determine the third actuation amount to reduce the difference between the target center wavelength and the estimated wavelength.
33. The system of clause 27, wherein:
the imaging operation comprises a multi-focal imaging operation,
the system further comprises a light source operating in a two-color mode,
the controller is further configured to operate the light source in the two-color mode by:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the estimating a center wavelength error comprises estimating a center wavelength error of the first beam of laser radiation.
34. A system comprising:
a light source configured to generate a light beam;
a first actuator configured to control movement of a first prism;
a second actuator configured to control movement of a second prism; and
a controller configured to:
determine a wavelength error of the light beam generated by the light source;
determine whether the wavelength error is greater than a first threshold value;
in response to determining that the wavelength error is greater than the first threshold value, cause the first actuator to move a first step size; and
in response to determining that the wavelength error is less than the first threshold value: determine an average wavelength error; and
determine whether the average wavelength error is greater than a second threshold value different than the first threshold value;
in response to determining that the average wavelength error is greater than the second threshold value, cause the first actuator to move a second step size and enable a low pass filter; and
in response to determining that the average wavelength error is less than the second threshold value, enable the low pass filter, update a voltage applied to a second actuator, and cause the first actuator to move a third step size.
35. The system of clause 34, wherein, to determine the wavelength error, the controller is further configured to:
measure a central wavelength of the light beam generated by the light source; and determine a difference between the central wavelength and a target center wavelength.
36. The system of clause 34, wherein the controller is further configured to:
determine whether a shot number of a pulse of the light source is a multiple of an update interval; and in response to determining that the shot number is equal to the update interval, update the voltage applied to the second actuator.
37. The system of clause 34, wherein the controller is further configured to disable the low pass filter and movement of a second actuator in response to determining that the wavelength error is greater than the first threshold value.
38. The system of clause 34, wherein the first step size is a fixed step size of the actuator.
39. The system of clause 34, wherein the second step size is a function of the wavelength error.
40. The system of clause 34, wherein the third step size is a function of the voltage applied to second actuator.
41. The system of clause 34, wherein, to cause the first actuator to move with the second step size, the controller is further configured to cause the first actuator to move every n pulses, with n being greater than one.
42. The system of clause 34, wherein the average wavelength error is based on the wavelength error and an average of a plurality of wavelength errors over a number of pulses.
43. The system of clause 34, wherein:
the system is configured to perform multi-focal imaging operations, and
the controller is further configured to operate the light source in a two-color mode by:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the determining the wavelength error of the light beam generated by the light source comprises determining a center wavelength error of the first beam of laser radiation.
44. A system for controlling a center wavelength for a multi-focal imaging operation, comprising:
an actuator configured to control movement of a prism; and
a controller configured to:
combine a dither waveform with an offset value for moving the actuator;
generate a pulse-to-pulse wavelength based on the dither waveform and the offset value;
generate a rolling average of the center wavelength based on the pulse-to-pulse wavelength for a plurality of pulses;
estimate a drift rate to predict a center wavelength of a future pulse; and
update the offset value based on the estimated drift rate.
45. The system of clause 44, wherein the offset value is based on a direct current (DC) voltage.
46. The system of clause 45, wherein an initial value of the DC voltage is zero volts.
47. The system of clause 44, wherein:
the offset value comprises a first offset value, and
the estimating the drift rate comprises estimating the drift rate based on the rolling average of the center wavelength, the first offset value, and a second offset value moving a second actuator controlling movement of a second prism.
48. The system of clause 47, wherein, to estimate the drift rate, the controller is further configured to estimate an accumulated center wavelength drift rate using a Kalman filter framework.
49. The system of clause 48, wherein, to estimate the drift rate, the controller is further configured to predict the center wavelength N pulses ahead of a current pulse.
50. The system of clause 49, wherein, to estimate the drift rate, the controller is further configured to convert the Kalman filter framework into a Kalman predictor to predict the center wavelength N pulses ahead of the current pulse.
51. The system of clause 44, wherein the pulse-to-pulse wavelength for a plurality of pulses comprises a wavelength of a current pulse.
52. The system of clause 44, wherein, to update the offset value, the controller is further configured to update the offset value based on the rolling average of the center wavelength at an end of a burst.

The breadth and scope of the embodiments should not be limited by any of the above-described exemplary embodiments, but should be defined only in accordance with the following claims and their equivalents.

1. A method for controlling a center wavelength for an imaging operation, the method comprising:
estimating a center wavelength error;
determining a first actuation amount for a first actuator controlling movement of a first prism based on the estimated center wavelength error;
actuating the first actuator based on the first actuation amount;
determining whether the first prism is off-center;
in response to determining that the first prism is off-center, determining a second actuation amount for the first actuator and determining a third actuation amount for a second actuator for controlling movement of a second prism; and
actuating the first actuator and the second actuator based on the second and third actuation amounts, respectively.

2. The method of claim 1, wherein the estimating the center wavelength error comprises:
calculating a first average of a center wavelength at odd bursts and a second average of the center wavelength at even bursts; and
determining an average of the first and second averages, wherein the center wavelength error is based on the average of the first and second averages.

3. The method of claim 1, wherein the determining the first actuation amount comprises:
determining a difference between a target center wavelength and the estimated center wavelength; and
determining the first actuation amount based on the difference between the target center wavelength and the estimated center wavelength.

4. The method of claim 3, wherein the determining the difference between the target center wavelength and the estimated center wavelength comprises determining the difference using a digital filter.

4. The method of claim 1, wherein the determining the third actuation amount for the second actuator is based on a position of the first prism after actuating the first actuator based on the second actuation amount.

6. The method of claim 5, wherein the determining the third actuation amount further comprises determining the third actuation amount to reduce the difference between the target center wavelength and the estimated wavelength.

7. The method of claim 1, wherein the imaging operation comprises a multi-focal imaging operation, and the method further comprises operating a light source in a two-color mode, wherein operating the light source in the two-color mode includes:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the estimating a center wavelength error comprises estimating a center wavelength error of the first beam of laser radiation.

8. A method for controlling a center wavelength, the method comprising:
determining a wavelength error of a light beam generated by a light source;
determining whether the wavelength error is greater than a first threshold value;
in response to determining that the wavelength error is greater than the first threshold value, moving a first actuator a first step size, the first actuator being configured to control movement of a first prism;
in response to determining that the wavelength error is less than the first threshold value:
determining an average wavelength error;
determining whether the average wavelength error is greater than a second threshold value different than the first threshold value;
in response to determining that the average wavelength error is greater than the second threshold value, moving the first actuator a second step size and enabling a low pass filter; and
in response to determining that the average wavelength error is less than the second threshold value, enabling the low pass filter, updating a voltage applied to a second actuator, and moving the first actuator a third step size, the second actuator being configured to control movement of a second prism.

9. (canceled)

10. (canceled)

11. The method of claim 8, further comprising disabling the low pass filter and movement of a second actuator in response to determining that the wavelength error is greater than the first threshold value.

12. (canceled)

13. (canceled)

14. The method of claim 8, wherein the third step size is a function of the voltage applied to second actuator.

15. The method of claim 8, wherein the moving the first actuator with the second step size comprises moving the first actuator every n pulses, with n being greater than one.

16-26. (canceled)

27. A system comprising:
a first actuator configured to control movement of a first prism;
a second actuator configured to control movement of a second prism; and
a controller configured to:
estimate a center wavelength error;
determine a first actuation amount for the first actuator based on the estimated center wavelength error;
cause the first actuator to actuate based on the first actuation amount;
determine whether the first prism is off-center;
in response to determining that the first prism is off-center, determine a second actuation amount for the first actuator and determine a third actuation amount for the second actuator; and
cause the first and second actuators to actuate based on the second and third actuation amounts, respectively.

28. The system of claim 27, wherein, to estimate the center wavelength error, the controller is further configured to:
calculate a first average of a center wavelength at odd bursts and a second average of the center wavelength at even bursts; and
determine an average of the first and second averages, wherein the center wavelength error is based on the average of the first and second averages.

29. The system of claim 27, wherein to determine the first actuation amount, the controller is further configured to:
determine a difference between a target center wavelength and the estimated center wavelength; and
determine the first actuation amount based on the difference between the target center wavelength and the estimated center wavelength.

30. The system of claim 29, wherein to determine the difference between the target center wavelength and the estimated center wavelength, the controller is further configured to determine the difference using a digital filter.

31. The system of claim 27, wherein the third actuation amount for the second actuator is based on a position of the first prism after actuating the first actuator based on the second actuation amount.

32. The system of claim 31, wherein, to determine the third actuation amount, the controller is further configured to determine the third actuation amount to reduce the difference between the target center wavelength and the estimated wavelength.

33. The system of claim 27, wherein:
the imaging operation comprises a multi-focal imaging operation,
the system further comprises a light source operating in a two-color mode,
the controller is further configured to operate the light source in the two-color mode by:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the estimating a center wavelength error comprises estimating a center wavelength error of the first beam of laser radiation.

34. A system comprising:
a light source configured to generate a light beam;
a first actuator configured to control movement of a first prism;
a second actuator configured to control movement of a second prism; and
a controller configured to:
determine a wavelength error of the light beam generated by the light source;
determine whether the wavelength error is greater than a first threshold value;
in response to determining that the wavelength error is greater than the first threshold value, cause the first actuator to move a first step size; and
in response to determining that the wavelength error is less than the first threshold value:
determine an average wavelength error; and
determine whether the average wavelength error is greater than a second threshold value different than the first threshold value;
in response to determining that the average wavelength error is greater than the second threshold value, cause the first actuator to move a second step size and enable a low pass filter; and
in response to determining that the average wavelength error is less than the second threshold value, enable the low pass filter, update a voltage applied to a second actuator, and cause the first actuator to move a third step size.

35. The system of claim 34, wherein, to determine the wavelength error, the controller is further configured to:
measure a central wavelength of the light beam generated by the light source; and
determine a difference between the central wavelength and a target center wavelength.

36-42. (canceled)

43. The system of claim 34, wherein:
the system is configured to perform multi-focal imaging operations, and
the controller is further configured to operate the light source in a two-color mode by:
generating, using a first laser chamber module, a first beam of laser radiation at a first wavelength;
generating, using a second laser chamber module, a second beam of laser radiation at a second wavelength; and
combining, using a beam combiner, the first and second laser radiations along a common output beam path,
wherein the determining the wavelength error of the light beam generated by the light source comprises determining a center wavelength error of the first beam of laser radiation.

44-52. (canceled)
